(19) United States
(12) Patent Application Publication
(10) Pub. No.: US 2026/0066247 A1
(43) Pub. Date: Mar. 5, 2026

(54) PLASMA PROCESSING METHOD AND PLASMA PROCESSING APPARATUS

(71) Applicant: Tokyo Electron Limited, Tokyo (JP)

(72) Inventors: Munehisa SEMOTO, Nirasaki City (JP); Kazushi KANEKO, Nirasaki City (JP); Mitsutoshi ASHIDA, Nirasaki City (JP)

(21) Appl. No.: 19/305,951

(22) Filed: Aug. 21, 2025

(30) Foreign Application Priority Data
Aug. 30, 2024 (JP) 2024-149862

(51) Int. Cl. H01J 37/32

(52) U.S. Cl. CPC H01J 37/3299; H01J 37/32146; H01J 2237/24564

(57) ABSTRACT

A plasma processing method, including: (A) supplying pulse power from an energy source into a processing container to generate plasma, (B) calculating a value which is at least one of an average value of a second level, a standard deviation of a pulse time of the second level, or a standard deviation of the second level, based on sensor data of the pulse power of a plurality of levels including a first level indicating a plasma OFF level and the second level indicating a plasma discharge level and on a plurality of pulse times respectively maintained at the plurality of levels, and (C) determining whether the plasma is normal or abnormal using the value calculated in process (B) and a preset threshold for the value calculated in process (B).

### CROSS-REFERENCE TO RELATED APPLICATION

This application is based upon and claims the benefit of priority from Japanese Patent Application No. 2024-149862, filed on Aug. 30, 2024, the entire contents of which are incorporated herein by reference.

### TECHNICAL FIELD

The present disclosure relates to a plasma processing method and a plasma processing apparatus.

### BACKGROUND

Patent Document 1 discloses a method of determining whether plasma ignition (lighting) occurs in a microwave radiator in which, for example, a sensor insertion hole is provided in each microwave radiator, and an electric field sensor or a plasma emission sensor is inserted into the sensor insertion hole to detect a power value of microwaves radiated from a surface wave plasma generation antenna of the microwave radiator.

### PRIOR ART DOCUMENT

### Patent Document

Patent Document 1: Japanese Patent Laid-open Publication No. 2013-077441

### SUMMARY

Embodiments of the present disclosure provide a plasma processing method, including: (A) supplying pulse power from an energy source into a processing container to generate plasma, (B) calculating a value which is at least one of an average value of a second level, a standard deviation of a pulse time of the second level, or a standard deviation of the second level, based on sensor data of the pulse power of a plurality of levels including a first level indicating a plasma OFF level and the second level indicating a plasma discharge level and on a plurality of pulse times respectively maintained at the plurality of levels, and (C) determining whether the plasma is normal or abnormal using the value calculated in process (B) and a preset threshold for the value calculated in process (B).

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a plasma processing apparatus according to a first embodiment.

FIG. 2 is a diagram illustrating an example of a microwave plasma source.

FIG. 3 is a cross-sectional view taken along line A-A in FIG. 1.

FIG. 4 is a diagram illustrating an example of a monitor system.

FIGS. 5A to 5C are diagrams illustrating an example of pulse power.

FIG. 6 is a flowchart illustrating an example of data reading and calculation process in a plasma processing method according to an embodiment.

FIG. 7 is a diagram illustrating an example of data read in the plasma processing method.

FIG. 8 is a flowchart illustrating an example of a calculation process during pulse-off status.

FIG. 9 is a flowchart illustrating an example of a calculation process during pulse non-discharge status.

FIG. 10 is a flowchart illustrating an example of a calculation process during pulse discharge status.

FIG. 11 is a flowchart illustrating an example of determination process in the plasma processing method according to the embodiment.

FIG. 12 is a schematic cross-sectional view illustrating an example of a plasma processing apparatus according to a second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a plasma processing method and a plasma processing apparatus will be described in detail with reference to the drawings. The plasma processing method and the plasma processing apparatus according to the present disclosure are not limited by these embodiments, and the embodiments below can be appropriately combined to an extent in which each configuration or each content of processing of the present disclosure is not contradicted.

Each drawing referred to below is a schematic diagram for convenience of explanation. Accordingly, details may sometimes be omitted, and dimensional ratios do not necessarily correspond to the actual ones.

### First Embodiment

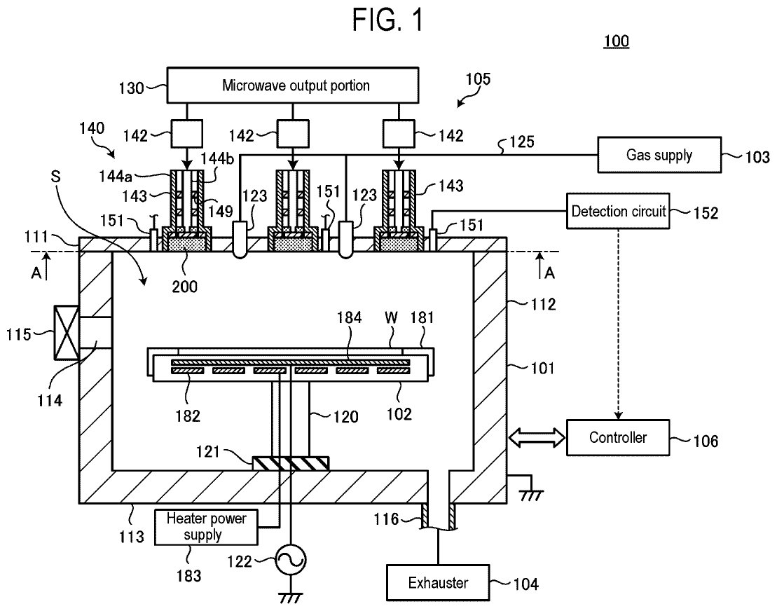

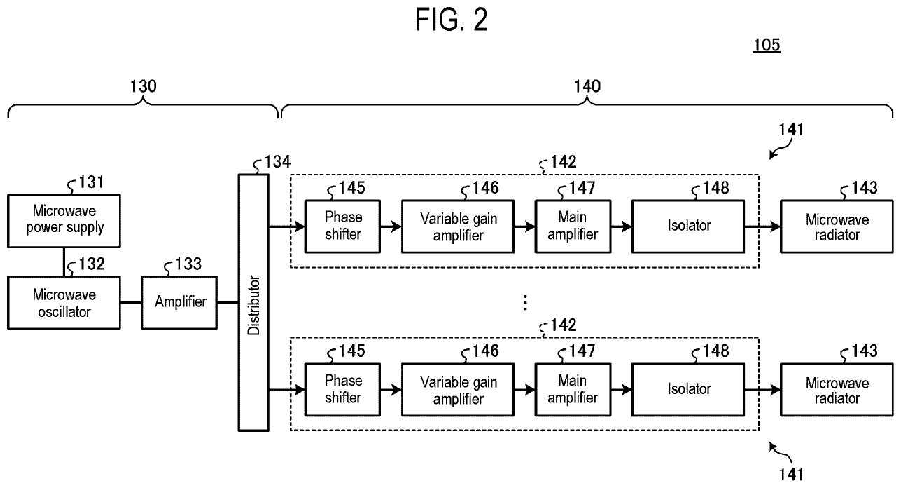

A plasma processing apparatus according to a first embodiment of the present disclosure will now be described with reference to FIGS. 1 and 2. FIG. 1 is a schematic cross-sectional view illustrating an example of a plasma processing apparatus according to a first embodiment. FIG. 2 is a diagram illustrating an example of a microwave plasma source.

A plasma processing apparatus 100 illustrated in FIG. 1 includes a processing container 101, a stage 102, a gas supply 103, an exhauster 104, a microwave plasma source 105, and a controller 106. The processing container 101 is formed in a cylindrical shape with a bottom made of a metal material such as aluminum, and provides a cylindrical processing space S inside the processing container 101. An upper portion of the processing container 101 is open. The processing container 101 has a plate-shaped ceiling wall portion 111, a bottom wall portion 113, and a side wall portion 112 connecting the ceiling wall portion 111 and the bottom wall portion 113.

A substrate W is loaded on the stage 102. The substrate W is not particularly limited as long as the substrate is subjected to plasma processing and includes, for example, a semiconductor wafer, a glass substrate, and the like. The gas supply 103 supplies a process gas into the processing container 101. The exhauster 104 evacuates the inside of the processing container 101. The microwave plasma source 105 is provided above the processing container 101 and introduces microwaves of 300 MHz to 3 THz for generating plasma into the processing container 101. The microwave plasma source 105 supplies pulsed microwave power into the processing container 101. Hereinafter, the pulsed microwave power or pulsed high-frequency power is also referred to as “pulse power”. The pulse power is constituted by a pulse-on time and a pulse-off time, and the pulse-on time and the pulse-off time constitute one cycle of a pulse. A reciprocal of the time period of one cycle is a pulse frequency, which is set from 1 Hz to 50 kHz. In addition, the pulse-on time divided by one cycle of the pulse is a duty, which is set from 1 to 99%. An average value of the high-frequency power during the pulse-on time becomes a set value of the pulse power.

The plasma processing apparatus 100 is an example of an apparatus that includes the microwave plasma source 105 and generates plasma using pulse power of microwaves output from the microwave plasma source 105 to perform plasma processing on a substrate. However, the plasma processing apparatus 100 is not limited thereto and may generate plasma using a radio frequency (RF) band of several kHz to 30 MHz or a high frequency of a very high frequency (VHF) band of 30 MHz to 300 MHz. The plasma processing apparatus 100 may be an apparatus that performs plasma processing, such as film formation processing, etching processing and the like on the substrate.

The ceiling wall portion 111 is disposed at an upper opening of the processing container 101. The ceiling wall portion 111 has a plurality of openings into which a microwave radiator 143 of the microwave plasma source 105 is fitted. The side wall portion 112 has a load/unload port 114 for loading and unloading the substrate W to and from a transfer chamber (not illustrated) adjacent to the processing container 101. The load/unload port 114 is configured to be opened and closed by a gate valve 115. The exhauster 104 is provided in an exhaust pipe 116 which is connected to the bottom wall portion 113, to evacuate the inside of the processing container 101 via the exhaust pipe 116. Thus, the exhauster 104 controls pressure inside the processing container 101.

The stage 102 is made of a disc-shaped ceramic and is supported on the bottom wall portion 113 by a ceramic support member 120 via an insulation member 121. A guide ring 181 for guiding the substrate W is provided on an outer edge of the stage 102. A heater 182 and an electrode 184 are embedded inside the stage 102. The heater 182 heats the substrate W via the stage 102 by being supplied with power from a heater power supply 183. A high-frequency bias for attracting ions is applied to the stage 102 from a high-frequency bias power supply 122. The high-frequency bias power supply 122 may not be provided depending on characteristics of plasma processing.

The gas supply 103 is connected to a plurality of gas introduction nozzles 123 via a gas supply pipe 125. The gas introduction nozzles 123 are fitted into openings formed in the ceiling wall portion 111 of the processing container 101. The gas supply 103 supplies the process gas into the processing container 101 from the plurality of gas introduction nozzles 123.

The microwave plasma source 105 includes a microwave output portion 130, an antenna portion 140, and a dielectric 200. The microwave output portion 130 generates microwaves and distributes output of the microwaves to a plurality of paths. The antenna portion 140 introduces the microwaves into the processing container 101 through the dielectric 200.

As illustrated in FIG. 2, the microwave output portion 130 includes a microwave power supply 131, a microwave oscillator 132, an amplifier 133, and a distributor 134. The microwave output portion 130 is an example of an energy source that supplies pulse power into the processing container 101. The microwave oscillator 132 is a solid state oscillator and generates microwaves of, for example, 915 MHz (e.g., phase-locked loop oscillation). The frequency of the microwaves is not limited to 915 MHz, and a frequency in a range of 700 MHz to 10 GHz including 2.45 GHz, 8.35 GHz, 5.8 GHz, or 1.98 GHz can be used. However, the frequency of the microwaves may be in the range of 300 MHz to 3 THz. The amplifier 133 amplifies the microwaves generated by the microwave oscillator 132. The distributor 134 distributes the microwaves amplified by the amplifier 133 to multiple paths. The distributor 134 distributes the microwaves while matching an impedance of an input side with an impedance of an output side. The microwave output portion 130 can also adjust frequency, power, bandwidth, and the like of the microwaves.

The antenna portion 140 includes a plurality of antenna modules 141. Each of the plurality of antenna modules 141 introduces the microwaves distributed by the distributor 134 into the processing container 101. The plurality of antenna modules 141 all have the same configurations. Each antenna module 141 includes an amplification portion 142 that mainly amplifies and outputs the distributed microwave, and a microwave radiation mechanism 143 that radiates the microwave output from the amplification portion 142 into the processing container 101.

The amplification portion 142 includes a phase shifter 145, a variable gain amplifier 146, a main amplifier 147, and an isolator 148. The phase shifter 145 shifts the phase of the microwave. The variable gain amplifier 146 adjusts a power level of the microwave input to the main amplifier 147. The main amplifier 147 is configured as a solid state amplifier. The isolator 148 isolates reflected microwaves that are reflected from an antenna portion of the microwave radiation mechanism 143 and directed to the main amplifier 147.

As illustrated in FIG. 1, the microwave radiation mechanism 143 has an outer conductor 144a and an inner conductor 144b that are provided coaxially, and a tuner 149. A space between the outer conductor 144a and the inner conductor 144b becomes a microwave transmission path. The tuner 149 matches an impedance of a load to a characteristic impedance of the microwave output portion 130. The microwaves are radiated into a space within the processing container 101 through the dielectric 200. Plasma is generated from the process gas by the energy of the pulse power of the microwaves that repeats ON and OFF.

The controller 106 processes computer-executable instructions that are executed by the plasma processing apparatus 100. The controller 106 may be configured to control each element of the plasma processing apparatus 100 so that the plasma processing apparatus 100 executes various processes. In one embodiment, all or a part of the controller 106 may be included in the plasma processing apparatus 100. The controller 106 may include a processor, a storage, and a communication interface (none illustrated). The controller 106 is implemented by, for example, a computer. The processor may be configured to perform various control operations by reading a program from the storage and executing the read program. The program may be stored in advance in the storage or may be acquired via a medium when necessary. The acquired program is stored in the storage, and the processor reads the program from the storage to execute the program. The medium may be any one of various computer-readable storage media or may be a communication line connected to the communication interface. The processor may be a central processing unit (CPU). The storage may include a random access memory (RAM), a read only memory (ROM), a hard disk drive (HDD), a solid state drive (SSD), or a combination thereof. The communication interface communicates with the plasma processing apparatus 100 via a communication line such as a local area network (LAN).

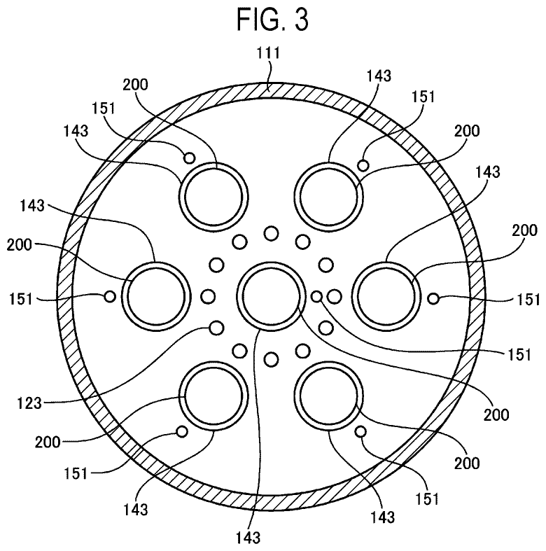

FIG. 3 is a cross-sectional view taken along line A-A in FIG. 1. As illustrated in FIG. 3, seven microwave radiators 143 are provided. One microwave radiator is disposed in a center of the ceiling wall portion 111 and the other microwave radiators are disposed around the one microwave radiator. These seven microwave radiators 143 are arranged so that adjacent microwave radiators 143 are spaced at equal intervals. The plurality of gas introduction nozzles 123 is arranged so as to surround the central microwave radiator 143. The number of the microwave radiators 143 is not limited to seven.

In a vicinity of each of the seven microwave radiators 143, a sensor insertion hole, which penetrates the ceiling wall portion 111 in a thickness direction, is provided. An electric field sensor 151 is inserted into the sensor insertion hole. The electric field sensor 151 may be inserted into the sensor insertion hole through a reflective cover (not illustrated) made of a cylindrical metal.

The electric field sensor 151 may be formed as a coaxial cable, and a tip end of the electric field sensor 151 may be a monopole antenna. The electric field sensor 151 is disposed in a vicinity of a position at which the pulse power of the microwaves is radiated within the processing container 101. The tip end of the electric field sensor 151 faces a back surface of the ceiling wall portion 111 to which the microwaves are radiated and is in contact with plasma through the ceiling wall portion 111. Thus, the microwaves radiated from the dielectric 200 into the processing container 101 can be directly monitored.

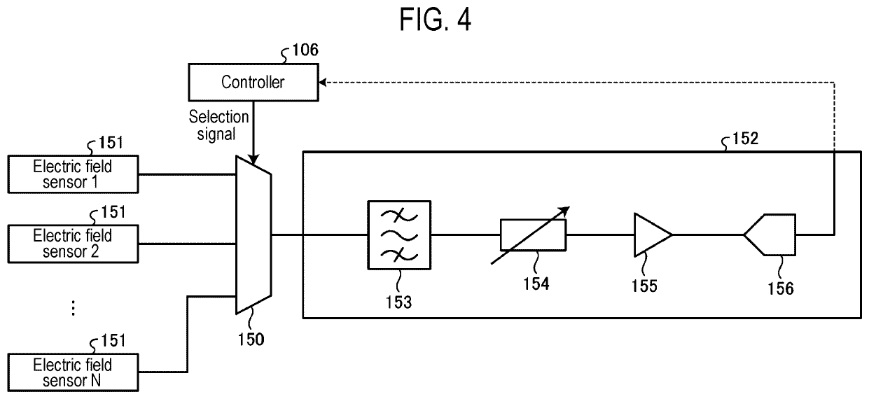

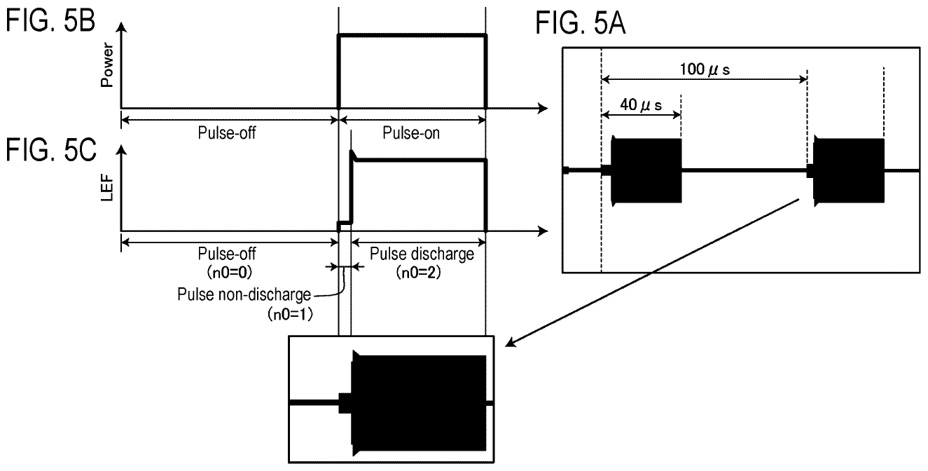

FIG. 4 is a diagram illustrating an example of a monitor system. FIGS. 5A to 5C are diagrams illustrating an example of pulse power. The monitor system includes a detection circuit 152 that detects a signal from the electric field sensor 151. The detection circuit 152 is connected to N electric field sensors 151 (in the present embodiment, the number of electric field sensors 151, N, is 7 in correspondence to the microwave radiators 143) via a multiplexer 150. The multiplexer 150 selects one electric field sensor 151 among the N electric field sensors 151 based on a selection signal received from the controller 106 and inputs sensor data detected by the selected electric field sensor 151 to the detection circuit 152.

The detection circuit 152 includes a band-pass filter 153, a variable attenuator 154, a detector 155, and an analog-to-digital converter (ADC) 156. The band-pass filter 153 passes a signal of a specific frequency band, which is output by the microwave output portion 130 among sensor data detected by the electric field sensor 151. The variable attenuator 154 attenuates a level (amplitude) of the signal of a specific frequency band that has passed through the band-pass filter 153. The variable attenuator 154 performs variable control on the amount of attenuation. The detector 155 samples an input signal at a preset sampling rate.

While a current value flowing through an electric field sensor 151 is proportional to an electric field, power passing through the ceiling wall portion 111 is proportional to the square of the electric field. Therefore, when the sensor data of the electric field sensor indicates a current value, the square of the current value detected by the electric field sensor 151 is proportional to the power. The detector 155 calculates the level of pulse power from the sampled sensor data accordingly and outputs the sensor data including the level of the pulse power to the ADC 156. The ADC 156 converts an input analog signal into a digital signal and transmits the digital signal to the controller 106 as the sensor data of the electric field sensor 151.

FIG. 5A illustrates an example of the sensor data of the electric field sensor 151 measured when the pulse power of microwaves, which has a pulse modulated frequency of 10 kHz and a duty of 40% and is output by the microwave output portion 130, is supplied. The microwaves repeat a pulse-on time of 40 s and a pulse-off time of 60 s in a cycle of 100 s. The duty is determined by the following equation:

$$Duty ( \% ) = ( pulse - on time / ( pulse - on time + pulse - off time ) ) \times 100$$

FIG. 5B illustrates the one cycle of pulse power output from the microwave output portion 130. FIG. 5C illustrates one cycle of sensor data detected by the electric field sensor 151 corresponding to the pulse power illustrated in FIG. 5B. In FIG. 5C, the sensor data is denoted as LEF. A power level of LEF detected during the pulse-off time is 0. A power level of LEF detected during the pulse-on time has either one of two values: a power level detected during a pulse non-discharge time, which appears at a very beginning of the pulse-on time, and a power level detected during a pulse discharge time after the pulse non-discharge time has elapsed. The power level detected during the pulse non-discharge time is a power level when plasma is not ignited (when plasma is not generated), while the power level detected during the pulse discharge time is a power level when plasma is ignited (when plasma is generated). Accordingly, the power levels having a difference in electric field strength therebetween are distinguished largely into two values. Immediately after the start of the pulse-on time, an increase of reflected microwaves causes the pulse non-discharge time. For this reason, the pulse discharge time during which plasma is actually generated may not coincide with the pulse-on time. In this case, a time difference occurs between the time at which the microwaves are pulsed-on and the time at which plasma is actually generated. This time difference corresponds to the pulse non-discharge time.

Therefore, the plasma processing apparatus 100 monitors this time difference in real time using the electric field sensor 151. The pulse-off time and the pulse-on time illustrated in FIG. 5B are set in a recipe stored in the storage and are controlled by the controller 106.

The power level of LEF detected during the pulse-off time of FIG. 5C corresponding to the pulse-off time of FIG. 5B indicates a plasma OFF level. The power levels of LEF detected during the pulse non-discharge time and pulse discharge time of FIG. 5C corresponding to the pulse-on time of FIG. 5B indicate a plasma non-discharge level and a plasma discharge level. At the plasma OFF level and the plasma non-discharge level, plasma is not generated or is not ignited. At the plasma discharge level, plasma is ignited by discharge and is generated.

The electric field sensor 151 detects sensor data of a plurality of levels including sensor data of a first level and sensor data of a second level. Alternatively, the sensor data may include sensor data of a third level. The plasma OFF level is an example of the “first level”. The plasma discharge level is an example of the “second level”. The plasma non-discharge level is an example of the “third level”.

These three levels increase in order of the first level being the smallest, the third level, and the second level, in terms of absolute values. The first level is zero or is a value close to zero. The third level has a value between the first level and the second level.

A pulse time of the first level is a time during which the first level is maintained and is the pulse-off time. The pulse time of the first level is calculated by, for example, multiplying the number of samplings of sensor data while the power level is continuously maintained at the first level, by the time of the first level. However, the pulse time of the first level is not limited thereto. If the sensor data includes a detection time, the pulse time of the first level may be calculated from the detection time included in the sensor data while the power level is continuously maintained at the first level. A pulse time of the second level is a time during which the second level is maintained and is the plasma discharge time. A pulse time of the third level is a time during which the third level is maintained and is the plasma non-discharge time. The pulse time of the second level and the pulse time of the third level may be calculated, for example, in the same manner as the calculation method of the first pulse time. The pulse time of the first level and the pulse time of the second level are greater than 0, and the pulse time of the third level is equal to or greater than 0.

### [Plasma Processing Method]

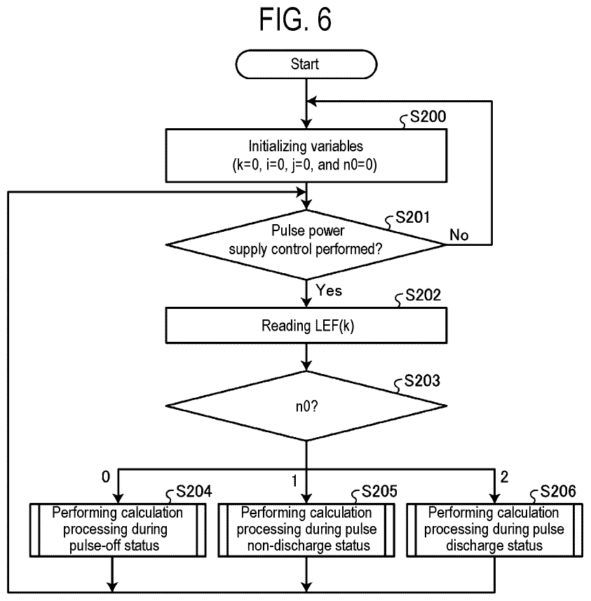

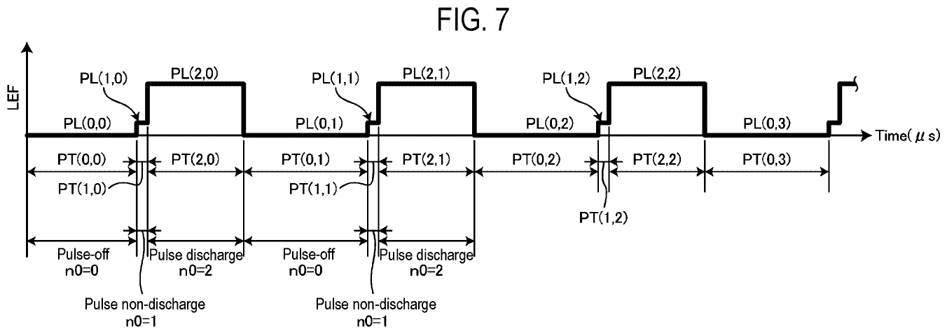

Next, data reading and calculation process in a plasma processing method according to an embodiment will be described with reference to FIGS. 6 and 7. FIG. 6 is a flowchart illustrating an example of the data reading and calculation process in the plasma processing method according to the embodiment. FIG. 7 is a diagram illustrating an example of data read in the plasma processing method.

In the following description, a variable n0 represents a status of a power level detected by the electric field sensor 151. As illustrated in FIG. 5C, the variable n0 of 0 represents a pulse-off status, n0 of 1 represents a status of pulse non-discharge, and n0 of 2 represents a status of pulse discharge. In addition, a variable k represents a sampling number of sensor data and a variable i represents the number of sensor data continuously read while the status of n0 is the same. A variable j represents the number of pulses, which is the number of repetitions of pulse power when one pulse is defined as one cycle of pulse power in which a plurality of levels is periodically repeated. In addition, PT(n0, j) represents a pulse time, and PL(n0, j) represents a power level. Of the pulse time, PT(0, j) is a pulse-off time, PT(1, j) is a pulse non-discharge time, and PT(2, j) is a pulse discharge time. Of the power level, PL(0, j) is a pulse-off level, PL(1, j) is a pulse non-discharge level, and PL(2, j) is a pulse discharge level.

### [Data Reading and Calculation Process]

In the data reading and calculation process illustrated in FIG. 6, the controller 106 controls initialization of variables, reading of sensor data, and calculation of statistical values such as an average value. The controller 106 continuously or periodically executes the processing of FIG. 6 to acquire sensor data sampled from the detection circuit 152.

### (Step S200: Initialization of Variables)

In step S200, the controller 106 initializes variables. Specifically, the controller 106 sets each of variables k, i, j, and n0 to 0.

### (Step S201: Determination of Pulse Power Control)

Next, in step S201, the controller 106 determines whether pulse power supply control of microwaves from the microwave output portion 130 into the processing container 101 is being performed. If the controller 106 determines that pulse power supply control is not being performed, the controller 106 repeats processes of steps S200 and S201. If the controller 106 determines that pulse power supply control is being performed, the controller 106 proceeds to step S202. Supplying pulse power from the microwave output portion 130 into the processing container 101 to generate plasma is an example of a process (A).

### (Step S202: Reading of Sensor Data)

Then, in step S202, the controller 106 reads LEF(k), which is sampled sensor data.

### (Step S203: Determination of Status)

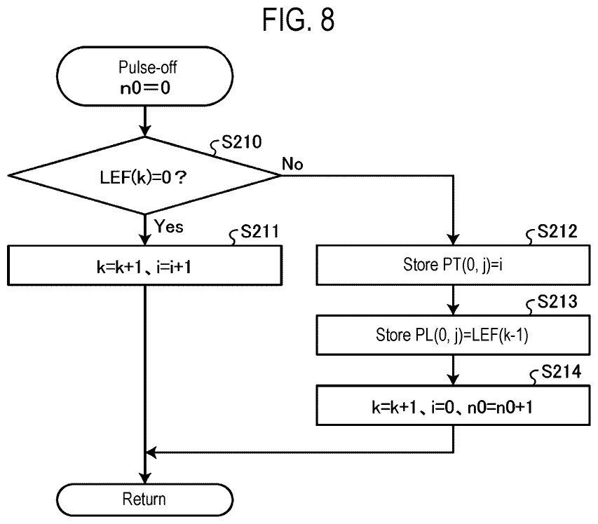

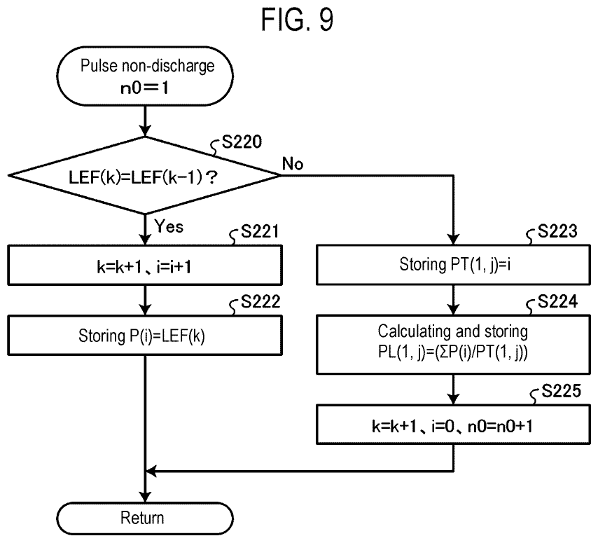

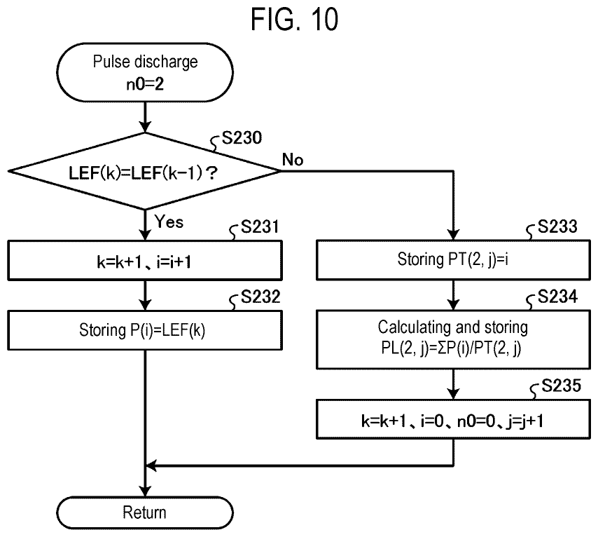

Then, in step S203, the controller 106 determines the status of n0. When n0 is 0, the controller 106 proceeds to step S204 to execute a calculation process during pulse-off status of FIG. 8. When n0 is 1, the controller 106 proceeds to step S205 to execute a calculation process during pulse non-discharge of FIG. 9. When n0 is 2, the controller 106 proceeds to step S206 to execute a calculation process during pulse discharge of FIG. 10.

### (Step S204: Calculation During Pulse-Off Status)

In step S204, the controller 106 executes a calculation process of a pulse-off level and a pulse-off time. FIG. 8 is a flowchart illustrating an example of a calculation process during pulse-off status.

In the calculation process during pulse-off status illustrated in FIG. 8, the controller 106 determines whether the read LEF(k) is equal to 0 in step S210. If it is determined that LEF(k) is equal to 0, the controller 106 proceeds to step S211 to add 1 to each of the variables k and i and returns to step S201 of FIG. 6.

If it is determined that the pulse power supply control is being performed in step S201, the controller 106 proceeds to step S202 to read LEF(k). Next, in step S203, the controller 106 executes the calculation process during pulse-off status in step S204 while n0 is 0. The controller 106 repeats processes of steps S201 to S204 of FIG. 6 and S210 and S211 of FIG. 8 while LEF(k) is determined to be 0 in step S210.

In step S210, if it is determined that LEF(k) is not 0, the controller 106 proceeds to step S212 to set a pulse-off time PT(0, j) to the variable i and stores the pulse-off time PT(0, j) in the storage. At this point, the variable i is the number of sensor data read continuously while the value of n0 is 0. Alternatively, the controller 106 may store a value obtained by multiplying a sampling time by the variable i as the actual pulse-off time PT(0, j).

Next, in step S213, the controller 106 sets a pulse-off level PL(0, j) to a value of LEF(k−1) that was read immediately before LEF(k). A horizontal axis of FIG. 7 represents time, and a vertical axis of FIG. 7 represents the power level of LEF. At this point, the controller 106 stores, in the storage, the pulse-off time PT(0, 0) and the pulse-off level PL(0, 0) in a pulse-off status (n0=0) from the i LEF values that have been read.

Next, in step S214, the controller 106 adds 1 to the variable k, sets the variable i to 0, adds 1 to the variable n0, and returns to step S201 of FIG. 6. At this point, n0 is 1, indicating a pulse non-discharge status. Therefore, the controller 106 proceeds from S201 to S203 to step S205.

### (Step S205: Calculation During Pulse Non-Discharge Status)

In step S205, the controller 106 executes a calculation process of a power level and a pulse non-discharge time during pulse non-discharge status. FIG. 9 is a flowchart illustrating an example of a calculation process during pulse non-discharge status.

In the calculation process during pulse non-discharge illustrated in FIG. 9, in step S220, the controller 106 determines whether LEF(k) is equal to LEF(k−1) that was read immediately before. If it is determined that LEF(k) is equal to LEF(k−1), the controller 106 proceeds to step S221 to add 1 to each of the variables k and i. However, the determination process of step S220 is not limited thereto and, for example, if LEF(k) is within a range of ±5% of LEF(k−1), LEF(k) may be determined to be equal to LEF(k−1). In addition, a range in which LEF(k) is determined to be equal to LEF(k−1) is not limited to ±5% of LEF(k−1).

Next, in step S222, the controller 106 sets P(i) to the value of LEF(k), stores P(i) in the storage and returns to step S201 of FIG. 6.

In step S201, if it is determined that pulse power supply control has been performed, the controller 106 proceeds to step S202 to read LEF(k). Next, in step S203, the controller 106 executes a calculation process during pulse non-discharge of step S205 while n0 is 1. The controller 106 repeats the processes of steps S201 to S203 and S205 of FIG. 6 and S220 to S222 of FIG. 9 while it is determined in step S220 that LEF(k) is equal to LEF(k−1).

In step S220, if it is determined that LEF(k) is different from LEF(k−1), the controller 106 proceeds to step S223 to set a pulse non-discharge time PT(1, j) to the variable i and store the pulse non-discharge time PT(1, j) in the storage. At this point, the variable i is the number of sensor data read continuously while the value of n0 is 1. Alternatively, the controller 106 may store a value obtained by multiplying a sampling time by the variable i as the actual pulse non-discharge time PT(1, j).

Next, in step S224, the controller 106 calculates an average value of power levels per unit time during pulse non-discharge using Equation (1) below and stores the average value in the storage as a pulse non-discharge level PL(1, j):

$$PL ( 1 , j ) = \sum P ( i ) / PT ( 1 , j ) \qquad ( 1 )$$

At this point, as illustrated in FIG. 7, the controller 106 calculates a pulse non-discharge time PT(1, 0) and a pulse non-discharge level PL(1, 0) during a pulse non-discharge status (n0=1) based on the i LEF values most recently read.

Next, in step S225, the controller 106 adds 1 to the variable k, sets the variable i to 0, adds 1 to the variable n0, and returns to step S201 of FIG. 6. At this point, n0 is 2, indicating a pulse discharge status. Therefore, the controller 106 proceeds from S201 to S203 to step S206.

(Step S206: Calculation during Pulse Discharge Status)

In step S206, the controller 106 executes a calculation process of a power level and a pulse discharge time during pulse discharge status. FIG. 10 is a flowchart illustrating an example of a calculation process during pulse discharge status.

In the calculation process during pulse discharge illustrated in FIG. 10, in step S230, the controller 106 determines whether LEF(k) is equal to LEF(k−1) that was read immediately before. If it is determined that LEF(k) is equal to LEF(k−1), the controller 106 proceeds to step S231 to add 1 to each of the variables k and i. However, the determination process of step S230 is not limited thereto and, for example, if LEF(k) is within a range of ±5% of LEF(k−1), it may be determined that LEF(k) is equal to LEF(k−1). In addition, a range in which LEF(k) is determined to be equal to LEF(k−1) is not limited to ±5% of LEF(k−1).

Next, in step S232, the controller 106 sets P(i) to the value of LEF(k), stores P(i) in the storage, and returns to step S201 of FIG. 6.

In step S201, if it is determined that the pulse power supply control has been performed, the controller 106 proceeds to step S202 to read LEF(k). Next, in step S203, the controller 106 executes a calculation process during pulse discharge status of step S206 while n0 is 2. The controller 106 repeats the processes of steps S201 to S203 and S206 of FIG. 6 and S230 to S232 of FIG. 10 while LEF(k) is determined to be equal to LEF(k−1) in step S230.

In step S230, if it is determined that LEF(k) is different from LEF(k−1), the controller 106 proceeds to step S233 to set a pulse discharge time PT(2, j) to the variable i and store the pulse discharge time PT(2, j) in the storage. At this point, the variable i is the number of sensor data read continuously while the value of n0 is 2. Alternatively, the controller 106 may also store a value obtained by multiplying a sampling time by the variable i as the actual pulse discharge time PT(2, j).

Next, in step S234, the controller 106 calculates an average value of power levels per unit time during pulse discharge status using Equation (2) below and stores the average value in the storage as a pulse discharge level PL(2, j):

$$PL ( 2 , j ) = \sum P ( i ) / PT ( 2 , j ) \qquad ( 2 )$$

At this point, as illustrated in FIG. 7, the controller 106 calculates a pulse discharge time PT(2, 0) and a pulse discharge level PL(2, 0) during a pulse discharge status (n0=2) based on the i LEF values most recently read.

Next, in step S235, the controller 106 adds 1 to the variable k, sets each of the variables i and n0 to 0, adds 1 to the variable j by 1, and returns to step S201 in FIG. 6. At this point, the variable n0 is 0, indicating the pulse-off status. Therefore, the controller 106 proceeds from steps S201 to S203 to step S204.

### (Steps S204 to S206: Repetition of Processes)

The controller 106 sequentially repeats the calculation processes of step S204, step S205, and step S206 based on the value of variable n0. By repeating the processes of steps S204 to S206, the controller 106 stores, in the storage, pulse times PT(0, 1), PT(1, 1), and PT(2, 1) and power levels PL(0, 1), PL(1, 1), and PL(2, 1) of a second cycle of pulse power illustrated in FIG. 7. The calculated pulse times PT and power levels PL are stored in the storage. The controller 106 continues to perform the repeated processes in a third cycle and subsequent cycles illustrated in FIG. 7. As a result, pulse times PT(0, 2), PT(1, 2), PT(2, 2), PT(0, 3), . . . and power levels PL(0, 2), PL(1, 2), PL(2, 2), PL(0, 3), . . . are stored in the storage.

### [Determination Process]

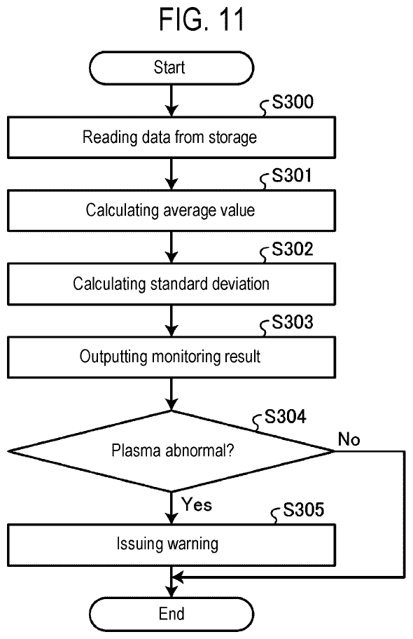

Next, a determination process related to the plasma processing method according to an embodiment will be described with reference to FIG. 11. FIG. 11 is a flowchart illustrating an example of the determination process in the plasma processing method according to the embodiment.

In the determination process illustrated in FIG. 11, the controller 106 determines whether a plasma is normal or abnormal by reading and using data stored in the storage, which is a result of the calculation process illustrated in FIG. 6.

### (Step S300: Reading of Data)

In step S300, the controller 106 reads the data stored in the storage, which is a result of executing the process illustrated in FIG. 6. The controller 106 may read the calculated pulse times PT and power levels PL based on sensor data of pulse power of a preset number of pulses, when one pulse is one cycle of pulse power in which a plurality of levels is periodically repeated. For example, when the number of pulses is set to “10”, the controller 106 reads pulse times PT(0, j−9) to PT(0, j), PT(1, j−9) to PT(1, j), and PT(2, j−9) to PT(2, j). The controller 106 also reads power levels PL(0, j−9) to PL(0, j), PL(1, j−9) to PL(1, j), and PL(2, j−9) to PL(2, j).

### (Step S301: Calculation of Average Value)

Next, in step S301, the controller 106 calculates an average value of the pulse times PT and an average value of the power levels PL. The controller 106 sets an average value PTa(0) of a pulse-off time to a value obtained by dividing a sum of the pulse times PT(0, j−9) to PT(0, j) by the number of pulses. The controller 106 also sets an average value PLa(0) of a pulse-off level to a value obtained by dividing a sum of the power levels PL(0, j−9) to PL(0, j) by the number of pulses. The controller 106 sets an average value PTa(1) of a pulse non-discharge time to a value obtained by dividing a sum of the pulse times PT(1, j−9) to PT(1, j) by the number of pulses. The controller 106 also sets an average value PLa(1) of a pulse non-discharge level to a value obtained by dividing a sum of the power levels PL(1, j−9) to PL(1, j) by the number of pulses. The controller 106 sets an average value PTa(2) of a pulse discharge time to a value obtained by dividing a sum of the pulse times PT(2, j−9) to PT(2, j) by the number of pulses. The controller 106 also sets an average value PLa(2) of a pulse discharge level to a value obtained by dividing a sum of power levels PL(2, j−9) to PL(2, j) by the number of pulses. Step S301 is an example of a process (B).

### (Step S302: Calculation of Standard Deviation)

Next, in step S302, the controller 106 calculates a standard deviation of the pulse times PT and a standard deviation of the power levels PL. The controller 106 calculates a standard deviation PTv(0) of the pulse-off time based on differences between each of PT(0, j−9) to PT(0, j) and the average value PTa(0). The controller 106 calculates a standard deviation PLv(0) of the pulse-off level based on differences between each of PL(0, j−9) to PL(0, j) and the average value PLa(0). The controller 106 calculates a standard deviation PTv(1) of the pulse non-discharge time based on differences between each of PT(1, j−9) to PT(1, j) and the average value PTa(1). The controller 106 calculates a standard deviation PLv(1) of the pulse non-discharge level based on differences between each of PL(1, j−9) to PL(1, j) and the average value PLa(1). The controller 106 calculates a standard deviation PTv(2) of the pulse discharge time based on differences between each of PT(2, j−9) to PT(2, j) and the average value PTa(2). The controller 106 calculates a standard deviation PLv(2) of the pulse discharge level based on differences between each of PL(2, j−9) to PL(2, j) and the average value PLa(2). Step S302 is an example of the process (B).

### (Step S303: Output of Monitoring Result)

Next, in step S303, the controller 106 outputs a monitoring result by the electric field sensor 151. The controller 106 may output, as the monitoring result, a value which is at least one of the average value PLa(2) of the pulse discharge level, the standard deviation PTv(2) of the pulse discharge time, or the standard deviation PLv(2) of the pulse discharge level.

For example, in addition to the average value PLa(2), the standard deviation PTv(2), and the standard deviation PLv(2), the controller 106 may also output the time of one cycle of pulse power and a duty of pulse power. In this case, the controller 106 sets the time of one cycle to the sum of PTa(0), PTa(1), and PTa(2). The controller 106 also sets the duty to a value obtained by dividing PTa(2) by the sum of PTa(0), PTa(1), and PTa(2).

### (Step S304: Determination of Abnormality)

Next, in step S304, the controller 106 determines whether plasma is normal or abnormal based on the value which is at least one of the average value PLa(2) of the pulse discharge level, the standard deviation PTv(2) of the pulse discharge time, or the standard deviation PLv(2) of the pulse discharge level and using a preset threshold for each of these values. Step S304 is an example of a process (C).

If it is determined that the value which is at least one of the average value PLa(2), the standard deviation PTv(2), or the standard deviation PLv(2) deviates from a range indicated by the corresponding threshold, the controller 106 may determine that plasma is abnormal. For example, if it is determined that the value which is at least one of the average value PLa(2), the standard deviation PTv(2), or the standard deviation PLv(2) deviates from a range of ±5% of the corresponding threshold, the controller 106 may determine that plasma is abnormal.

### (Step S305: Warning Process)

If it is determined that plasma is abnormal in step S304, the controller 106 proceeds to step S305 to issue a warning. Step S305 is an example of a process (D). The controller 106 may issue the warning through at least one of monitor display or sound. Step S305 may also be omitted.

If it is determined that plasma is abnormal in step S304, the controller 106 may stop supplying pulse power of the microwaves. Stopping the supply of the pulse power is an example of a process (E). For example, if it is determined that the value which is at least one of the average value PLa(2), the standard deviation PTv(2), or the standard deviation PLv(2) deviates from a range of ±6% of the threshold, the controller 106 may stop supplying the pulse power of the microwaves. However, if it is determined that the value which is at least one of the average value PLa(2), the standard deviation PTv(2), or the standard deviation PLv(2) deviates from a range of ±5% of the threshold but is within a range of ±6%, the controller 106 may issue a warning but may perform supply control, so that the supply of the microwaves is not stopped.

If it is determined that plasma is abnormal in step S304, the controller 106 may perform feedback control with respect to at least one of the power level PL or the pulse time PT based on data read from the storage. Thereby, precision of plasma processing on the substrate W can be improved.

For example, the controller 106 may correct a pulse discharge level based on data read from the storage and supply pulse power of the corrected pulse discharge level.

When it is determined that plasma is abnormal in step S304, the controller 106 may correct a pulse discharge time based on a pulse non-discharge time, based on the data read from the storage, and supply pulse power of the pulse discharge level at the corrected pulse discharge time.

For example, when a certain number of pulses is integrally processed as one unit of processing data, the controller 106 may perform control so that a total pulse discharge time of the certain number of pulses is equal to a preset total pulse-on time of the certain number of pulses. If the total times are not equal, the controller 106 may add or subtract one of pulse discharge times of the certain number of pulses based on the pulse non-discharge time, so that the total pulse discharge time of the certain number of pulses is equal to the preset total pulse-on time of the certain number of pulses. This enables the controller 106 to supply pulse power of a preset plasma discharge level at a preset total pulse-on time of the certain number of pulses.

Alternatively, for example, the controller 106 may perform control so that a pulse discharge time of the second pulse is equal to a preset pulse-on time, based on a pulse non-discharge time or a pulse discharge time of the first pulse. If it is determined that the pulse discharge time of the second pulse is not equal to the preset pulse-on time, the controller 106 may perform feedback control to adjust the pulse discharge time of the second pulse based on the pulse non-discharge time of the first pulse, so that the pulse discharge time of the second pulse is equal to the preset pulse-on time. The controller 106 may continuously perform the control in the order of the third pulse, the fourth pulse, and so on so that the pulse discharge time of the next pulse is adjusted based on the pulse non-discharge time of the previous pulse.

Alternatively, for example, the controller 106 may perform control so that the pulse discharge time of the first pulse is equal to a preset pulse-on time, based on the pulse non-discharge time or the pulse discharge time. If it is determined that the pulse discharge time of the first pulse is not equal to the preset pulse-on time, the controller 106 may perform feedback control to adjust the pulse discharge time of the first pulse based on the pulse non-discharge time of the first pulse, so that the pulse discharge time of the first pulse is equal to the preset pulse-on time. The controller 106 may continuously perform the control in the order of the second pulse, the third pulse, and so on.

### Effects of First Embodiment

As described above, the plasma processing method includes the processes (A) to (C). Process (A) supplies pulse power from an energy source into the processing container 101 to generate plasma. Process (B) calculates the value which is at least one of an average value of a pulse discharge level, a standard deviation of a pulse time of the pulse discharge level, or a standard deviation of the pulse discharge level. This calculation is based on sensor data of the pulse power of a plurality of levels including a pulse-off level indicating a plasma-off level and a pulse discharge level indicating a plasma discharge level and on a plurality of pulse times maintained at the plurality of levels. Process (C) determines whether the plasma is normal or abnormal using the at least one value calculated in process (B) and a preset threshold for the at least one value calculated in process (B).

Thereby, monitoring precision of the plasma generated by the supplied pulse power can be improved. As a result, whether the plasma is normal or abnormal can be determined with high precision.

The plurality of levels includes a third level between a first level and a second level, and the controller 106 may execute processes (B) and (C) when a pulse time of the third level is greater than 0.

### Second Embodiment

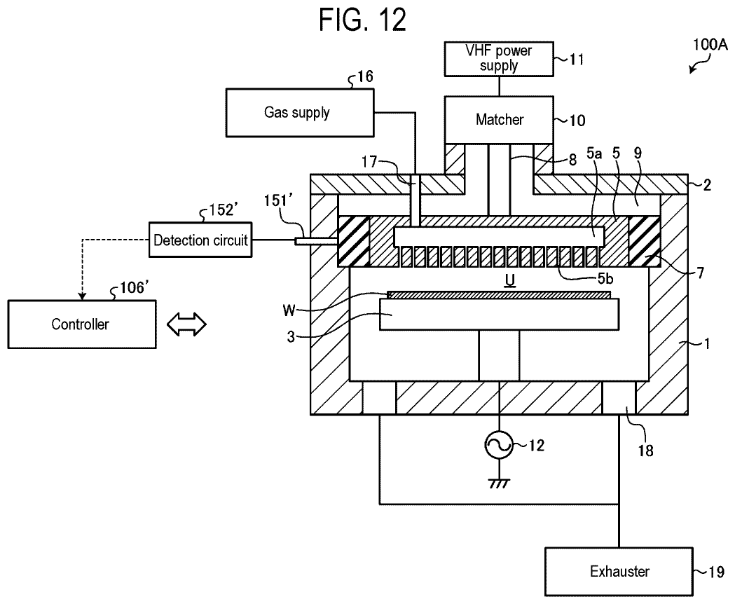

Next, a plasma processing apparatus according to a second embodiment of the present disclosure will be described with reference to FIG. 12. FIG. 12 is a schematic cross-sectional view illustrating an example of the plasma processing apparatus according to the second embodiment. A plasma processing apparatus 100A is an example of an apparatus that includes a VHF power supply 11 and generates plasma using pulse power of a VHF output from the VHF power supply 11 to perform plasma processing on a substrate.

The plasma processing apparatus 100A includes a processing container 1, a lid 2, and a stage 3. The processing container 1 is formed in a cylindrical shape with a bottom and has an upper portion which opens. The lid 2 is configured to seal the upper opening of the processing container 1. A processing chamber U is provided inside the processing container 1. The stage 3 is located inside the processing chamber U, and a substrate W is loaded on the stage 3. The substrate W is subjected to plasma processing.

The plasma processing apparatus 100A also includes an upper electrode 5 and a dielectric ring 7. The upper electrode 5 faces the stage 3. The upper electrode 5 is disc-shaped and has a metallic shower plate structure.

A space surrounded by the upper electrode 5, the lid 2, and the processing container 1 constitute a waveguide path 9. The waveguide path 9 is located along the upper electrode 5. VHF power of a VHF band is transmitted through the waveguide path 9. However, high-frequency power of a UHF band may be transmitted through the waveguide path 9.

A diffusion chamber 5a and a plurality of gas holes 5b are formed inside the upper electrode 5. The plurality of gas holes 5b are through holes that penetrate a lower surface of the upper electrode 5 to connect the diffusion chamber 5a and the processing chamber U. The dielectric ring 7 is an annular member having an inner diameter slightly larger than the diameter of the upper electrode 5 and an outer diameter slightly smaller than the diameter of the inner surface of the processing container 1, and partitions the processing chamber U of a vacuum space and the waveguide path 9 of an atmospheric space. The dielectric ring 7 is located at an end of the waveguide path 9 between the upper electrode 5 and the processing container 1.

The lid 2 is formed in a disc shape and has an opening at the center. A matcher 10 is located so as to block the central opening of the lid 2 at an upper portion of the plasma processing apparatus 100A. The matcher 10 is connected to the upper electrode via a transmission line 8. The transmission line 8 may be composed of a waveguide pipe or a coaxial cable capable of transmitting high-frequency power of VHF band or UHF band.

The VHF power supply 11 is electrically connected to the upper electrode 5 through the matcher 10 and the transmission line 8. The VHF power supply 11 outputs a VHF to supply pulse power of the VHF into the processing container 1. The VHF power supply 11 is an example of an energy source that supplies pulse power into the processing container 101. The matcher 10 has a matching circuit for matching the impedance of a load side (upper electrode 5 side) of the VHF power supply 11 to the output impedance of the VHF power supply 11.

The VHF is transmitted through the waveguide path 9 via the matcher 10 and the transmission line 8, and is radiated to the processing chamber U through the dielectric ring 7. Thereby, pulse power of the VHF for generating plasma is supplied to the processing chamber U. In the pulse power of the VHF, pulse-off time and pulse-on time illustrated in FIG. 5B are repeated periodically.

The plasma processing apparatus 100A also includes a gas supply 16. The gas supply 16 is connected to a gas supply pipe 17. The gas supply pipe 17 penetrates the lid 2, the waveguide path 9, and the upper electrode 5 to communicate with the diffusion chamber 5a. A process gas is supplied from the gas supply 16, diffused in the diffusion chamber 5a through the gas supply pipe 17, and then supplied into the processing chamber U through the plurality of gas holes 5b.

The stage 3 is electrically connected to a high-frequency power supply 12. The high-frequency power supply 12 applies, to the stage, a high-frequency bias voltage of a RF band for mainly attracting ions in plasma. The high-frequency power supply 12 can output continuous wave power or pulse power. However, the high-frequency power supply 12 may not be provided.

A gas exhaust port 18 is formed at the bottom of the processing container 1. The gas exhaust port 18 is connected to an exhauster 19. The exhauster 19 evacuates gas inside the processing chamber U to the outside through the gas exhaust port 18. The processing container 1 has a load/unload port (not illustrated) for loading and unloading the substrate W to and from a transfer chamber (not illustrated). The load/unload port is configured to be opened and closed by a gate valve (not illustrated).

A controller 106′ processes computer-executable instructions that are executed by the plasma processing apparatus 100A to execute various processes. The controller 106′ may be configured to control each element of the plasma processing apparatus 100A so that the plasma processing apparatus 100A executes various processes.

The plasma processing apparatus 100A includes an electric field sensor 151′. The electric field sensor 151′ is inserted into a through hole that penetrates a side wall of the processing container 1 from an outer surface of the processing container 1. A tip end of the electric field sensor 151′ comes into contact with the dielectric ring 7. The electric field sensor 151′ is positioned close to plasma, corresponding to the position of the dielectric ring 7 through which the pulse power of the VHF is radiated. The electric field sensor 151′ may have the same structure as the electric field sensor 151 according to the first embodiment.

When the process gas is introduced into the processing container 1, and the pulse power of the VHF is introduced into the processing chamber U while the inside of the processing chamber U is depressurized to a pressure at which plasma can be generated by the exhauster 19, plasma is generated by the pulse power of the VHF. The electric field sensor 151′ monitors this plasma.

A detection circuit 152′ has the same configuration as the detection circuit 152 illustrated in FIG. 4. In the second embodiment, since there is only one electric field sensor 151′, the multiplexer 150 illustrated in FIG. 4 is unnecessary, and the electric field sensor 151′ is directly connected to the detection circuit 152′. However, in the second embodiment, a plurality of electric field sensors 151′ may be arranged in a circumferential direction or in a thickness direction of the dielectric ring 7.

### Effects of Second Embodiment

In the plasma processing apparatus 100A described above, a controller 106′ controls the plasma processing method of FIGS. 6 and 11 described in the first embodiment, by acquiring sensor data from the electric field sensor 151′ installed so as to be in contact with a dielectric (the dielectric ring 7) inside a vacuum container (the processing container 1) that determines the state of plasma. Thereby, monitoring precision of the plasma generated by the supply of the pulse power of the VHF can be increased. As a result, whether the plasma is normal or abnormal can be determined with high precision.

It should be noted that the embodiments disclosed herein are exemplary in all aspects and are not restrictive. In practice, the above-described embodiments may be implemented in various forms. Furthermore, the embodiments may be omitted, replaced, or modified in various ways without departing from the scope and spirit of the appended claims.

Hereinafter, preferred aspects of the present disclosure will be additionally stated.

### ASPECTS OF PRESENT DISCLOSURE

(1) A plasma processing method including: (A) supplying pulse power from an energy source into a processing container to generate plasma, (B) calculating a value which is at least one of an average value of a second level, a standard deviation of a pulse time of the second level, or a standard deviation of the second level, based on sensor data of the pulse power of a plurality of levels including a first level indicating a plasma OFF level and the second level indicating a plasma discharge level and on a plurality of pulse times respectively maintained at the plurality of levels and (C) determining whether the plasma is normal or abnormal using the value calculated in process (B) and a preset threshold for the value calculated in process (B).
(2) The plasma processing method of (1), wherein the plurality of levels includes a third level between the first level and the second level, and the processes (B) and (C) are executed when the pulse time of the third level is greater than 0.
(3) The plasma processing method of (1) or (2), wherein, in the process (B), the sensor data of the pulse power is measured using an electric field sensor provided in the processing container.
(4) The plasma processing method of (3), wherein the electric field sensor is disposed in correspondence to a position at which the pulse power is radiated within the processing container.
(5) The plasma processing method of (1) to (4), further including: (D) issuing a warning upon determining that the plasma is abnormal.
(6) The plasma processing method of (2), wherein, upon determining that the plasma is abnormal, correcting the second level and supplying pulse power of the corrected second level.
(7) The plasma processing method of (2), wherein, upon determining that the plasma is abnormal, correcting the pulse time of the second level by the pulse time of the third level and supplying pulse power of the second level at the corrected pulse time of the second level.
(8) The plasma processing method of (1) to (5), further including: (E) stopping the supply of the pulse power upon determining that the plasma is abnormal.
(9) The plasma processing method of (1) to (8), wherein, in the process (B), one cycle of the pulse power in which the plurality of levels is periodically repeated is defined as one pulse, and the value which is at least one of the average value of the second level, the standard deviation of the pulse time of the second level, or the standard deviation of the second level is calculated based on the sensor data of the pulse power of a preset number of pulses and on the plurality of pulse times respectively maintained at the plurality of levels.
(10) A plasma processing apparatus including: a processing container, an energy source configured to supply pulse power into the processing container, and a controller, wherein the controller controls a process including (A) supplying the pulse power from an energy source into the processing container to generate plasma, (B) calculating a value which is at least one of an average value of a second level, a standard deviation of a pulse time of the second level, based on sensor data of the pulse power of a plurality of levels including a first level indicating a plasma OFF level and the second level indicating a plasma discharge level and on a plurality of pulse times respectively maintained at the plurality of levels, and (C) determining whether the plasma is normal or abnormal using the value calculated in process (B) and a preset threshold for the value calculated in process (B).

According to the present disclosure in some embodiments, it is possible to increase monitoring precision of plasma generated by the supply of pulse power.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing method, comprising:
(A) supplying pulse power from an energy source into a processing container to generate plasma;
(B) calculating a value which is at least one of an average value of a second level, a standard deviation of a pulse time of the second level, or a standard deviation of the second level, based on sensor data of the pulse power of a plurality of levels including a first level indicating a plasma-off level and the second level indicating a plasma discharge level, and a plurality of pulse times respectively maintained at the plurality of levels; and
(C) determining whether the plasma is normal or abnormal using the value calculated in process (B) and a preset threshold for the value calculated in process (B).

2. The plasma processing method of claim 1, wherein the plurality of levels includes a third level between the first level and the second level, and the processes (B) and (C) are executed when the pulse time of the third level is greater than 0.

3. The plasma processing method of claim 1, wherein, in the process (B), the sensor data of the pulse power is measured using an electric field sensor provided in the processing container.

4. The plasma processing method of claim 3, wherein the electric field sensor is disposed in correspondence to a position at which the pulse power is radiated within the processing container.

5. The plasma processing method of claim 1, further comprising:
(D) issuing a warning upon determining that the plasma is abnormal.

6. The plasma processing method of claim 2, wherein, upon determining that the plasma is abnormal, correcting the second level and supplying pulse power of the corrected second level.

7. The plasma processing method of claim 2, wherein, upon determining that the plasma is abnormal, correcting the pulse time of the second level by the pulse time of the third level and supplying pulse power of the second level at the corrected pulse time of the second level.

8. The plasma processing method of claim 1, further comprising:
(E) stopping the supply of the pulse power upon determining that the plasma is abnormal.

9. The plasma processing method of claim 4, further comprising:
(E) stopping the supply of the pulse power upon determining that the plasma is abnormal.

10. The plasma processing method of claim 1, wherein, in the process (B), one cycle of the pulse power in which the plurality of levels is periodically repeated is defined as one pulse, and the value which is at least one of the average value of the second level, the standard deviation of the pulse time of the second level, or the standard deviation of the second level is calculated based on the sensor data of the pulse power of a preset number of pulses and on the plurality of pulse times respectively maintained at the plurality of levels.

11. The plasma processing method of claim 4, wherein, in the process (B), one cycle of the pulse power in which the plurality of levels is periodically repeated is defined as one pulse, and the value which is at least one of the average value of the second level, the standard deviation of the pulse time of the second level, or the standard deviation of the second level is calculated based on the sensor data of the pulse power of a preset number of pulses and on the plurality of pulse times respectively maintained at the plurality of levels.

12. A plasma processing apparatus, comprising:
a processing container,
an energy source configured to supply pulse power into the processing container, and
a controller,
wherein the controller controls a process including:
(A) supplying the pulse power from the energy source into the processing container to generate plasma;
(B) calculating a value which is at least one of an average value of a second level, a standard deviation of a pulse time of the second level, or a standard deviation of the second level, based on sensor data of the pulse power of a plurality of levels including a first level indicating a plasma OFF level and the second level indicating a plasma discharge level and on a plurality of pulse times respectively maintained at the plurality of levels; and
(C) determining whether the plasma is normal or abnormal using the value calculated in process (B) and a preset threshold for the value calculated in process (B).
